(19) United States
(12) Patent Application Publication
(10) Pub. No.: US 2010/0127374 A1
(43) Pub. Date: May 27, 2010

(54) Multi-stack semiconductor package, semiconductor module and electronic signal processing system including thereof

(75) Inventor: Yun-Rae Cho, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,563

(22) Filed: Nov. 24, 2009

(30) Foreign Application Priority Data
Nov. 24, 2008 (KR) 10-2008-0117127

(51) Int. Cl. H01L 25/16

(52) U.S. Cl. 257/687; 257/E25.03

(57) ABSTRACT

Multi-stack semiconductor packages and application technologies are provided. The multi-stack semiconductor package may include stacked semiconductor packages which may include a topmost semiconductor package and a bottommost semiconductor package. Each of the unit semiconductor packages may include a substrate, a semiconductor chip formed on the substrate, a molding material filled around the semiconductor chip on the substrate, and an adhesive layer formed on the semiconductor chip and the molding material. The semiconductor chip and the substrate of a semiconductor package may each include conductive vias providing an electrical connection between the semiconductor packages. The substrate of the upper semiconductor package stacked in an upper portion may be directly adhered onto the adhesive layer of the lower semiconductor package stacked in a lower portion.

### PRIORITY STATEMENT

This application claims priority under 35 U.S.C. §119 to Korean Patent Application No. 10-2008-0117127, filed on Nov. 24, 2008, in the Korean Intellectual Property Office (KIPO), the entire contents of which are herein incorporated by reference.

### BACKGROUND

1. Field

Example embodiments relate to multi-stack semiconductor packages, semiconductor modules, and electronic signal processing systems, and methods of fabricating the multi-stack semiconductor packages.

2. Description of Related Art

To increase the processing or storage capacity of a single semiconductor device, research on technology for increasing a degree of integration of the semiconductor device is under way. However, because it is difficult to increase the degree of integration of the semiconductor device, a method of increasing the processing or storage capacity of a semiconductor device by connecting a plurality of semiconductor devices has been proposed. The research in this technical field has gone in two main directions, namely, stacking semiconductor chips in a wafer state and stacking semiconductor devices in a finished package state. However, the two techniques described above are disadvantageous in that yield is relatively low, testing is relatively difficult, sizes of the semiconductor packages are unnecessarily increased, and cost is relatively high. Also, because there is a limitation in terms of performance, it may be impossible to apply the above-described techniques to the next-generation of semiconductor devices requiring increased precision.

### SUMMARY

Example embodiments provide a multi-stack semiconductor package, a semiconductor module including a multi-stack semiconductor package, an electronic signal processing system having a semiconductor module including a multi-stack semiconductor package, and a method of fabricating a multi-stack semiconductor package.

In accordance with example embodiment, a multi-stack semiconductor package may include a stacked semiconductor packages including a topmost semiconductor package and a bottommost semiconductor package. Each of the semiconductor packages may include a substrate including at least one via land on a first surface of the substrate, at least one circuit land on a second surface of the substrate and electrically connected to the at least one via land, and at least one test land on the second surface of the substrate and electrically connected to the at least one circuit land. Each of the semiconductor packages may also include a semiconductor chip on the substrate, the semiconductor chip including at least one conductive chip via passing through the semiconductor chip, and at least one lower via pad on a first surface of the semiconductor chip, the at least one lower via pad being electrically connected to the at least one conductive chip via and the at least one via land. Each of the semiconductor packages may further include a molding material around the semiconductor chip on the substrate, and an adhesive layer on the semiconductor chip and the molding material. In accordance with example embodiments, the substrate of an upper semiconductor package stacked in an upper portion of the multi-stack semiconductor package may be adhered to the adhesive layer of a lower semiconductor package stacked in a lower portion of the multi-stack semiconductor package.

Example embodiments include a multi-stack semiconductor package including multiple stacked semiconductor packages which may include a topmost semiconductor package and a bottommost semiconductor package. Each of the unit semiconductor packages may include a substrate, a semiconductor chip formed on the substrate, a molding material filled around the semiconductor chip on the substrate, and an adhesive layer formed on the semiconductor chip and the molding material. The semiconductor chip may include conductive chip vias passing through the semiconductor chip and lower via pads formed on one surface of the semiconductor chip and electrically connected to the conductive chip vias. The substrate may include via lands formed on one surface of the substrate and electrically connected to the lower via pads, circuit lands formed on the other surface of the substrate and electrically connected to the via lands, and test lands formed on the one surface of the substrate electrically connected to the circuit lands. The substrate of the upper semiconductor package may be stacked in an upper portion and may be directly adhered onto the adhesive layer of the lower semiconductor package stacked in a lower portion.

Example embodiments include a multi-stack semiconductor package including multiple stacked unit semiconductor packages that may include a topmost semiconductor package, a bottommost semiconductor package, and at least one intermediate semiconductor packages. Each of the semiconductor packages may include a substrate, a semiconductor chip formed on the substrate, a molding material filled around the semiconductor chip on the substrate, and an adhesive layer formed on the semiconductor chip and the molding material. The semiconductor chip may include conductive chip vias passing through the semiconductor chip and lower via pads formed on one surface of the semiconductor chip and electrically connected and aligned to the conductive chip vias. The substrate may include via lands formed on one surface of the substrate and electrically connected and aligned to the lower via pads circuit lands formed on the other surface of the substrate and electrically connected to the via lands and test lands on the other surface of the substrate electrically connected to the circuit lands, respectively. The substrate of the upper semiconductor package stacked in an upper portion may be directly adhered onto the adhesive layer of the lower semiconductor package stacked in a lower portion.

Example embodiments include a semiconductor module including a plurality of multi-stack semiconductor packages disposed on a module substrate, each of the multi-stack semiconductor packages may include multiple stacked semiconductor packages including a topmost semiconductor package and a bottommost semiconductor package. Each of the semiconductor packages may include a substrate, a semiconductor chip formed on the substrate, a molding material filled around the semiconductor chip on the substrate, and an adhesive layer formed on the semiconductor chip and the molding material. The semiconductor chip may include conductive chip vias passing through the semiconductor chip and lower, excepting the bottommost semiconductor packages, via pad formed on one surface of the semiconductor chip and electrically to the conductive chip vias. The substrate may include via lands formed on one surface of the substrate and electrically connected to the lower via pads, circuit lands formed on the other surface of the substrate and electrically connected to the via lands, and test lands formed on the one surface of the substrate electrically connected to the circuit lands, respectively. The substrate of the upper semiconductor package stacked in an upper portion may be directly adhered onto the adhesive layer of the lower semiconductor package stacked in a lower portion, and a plurality of contact terminals on the module substrate. The test lands of the substrate and the contact terminals are electrically connected to each other, respectively.

Example embodiments include an electronic signal processing system including a central processing unit configured to process an electronic signal, a command unit configured to output a signal processing command to the central processing unit, an output unit configured to externally display the signal processed by the central processing unit, a semiconductor module configured to exchange electronic data with the central processing unit and store the data, a memory interface disposed between the central processing unit and the semiconductor module, and a communicator configured to receive a signal to be processed by the central processing unit from another central processing unit and transmit a signal processed by the central processing unit to another central processing unit. The semiconductor module may include a plurality of multi-stack semiconductor packages disposed on a module substrate. Each of the multi-stack semiconductor packages may include multiple stacked semiconductor packages including a topmost semiconductor package and a bottommost semiconductor package. The semiconductor packages may include a substrate, a semiconductor chip formed on the substrate, a molding material filled around the semiconductor chip on the substrate, and an adhesive layer formed on the semiconductor chip and the molding material. The semiconductor chip may include conductive chip vias passing through the semiconductor chip, and lower via pads formed on one surface of the semiconductor chip and electrically connected to the conductive chip vias. The substrate may include via lands formed on one surface of the substrate and electrically connected to the lower via pads, circuit lands formed on the other surface of the substrate and electrically connected to the via lands, and test lands formed on the one surface of the substrate electrically connected to the circuit lands, respectively. The substrate of the upper semiconductor package stacked in an upper portion may be directly adhered onto the adhesive layer of the lower semiconductor package stacked in a lower portion, and a plurality of contact terminals on the module substrate, wherein the test lands of the substrate and the contact terminals are electrically connected to each other, respectively.

Example embodiments include a method of fabricating a multi-stack semiconductor package, including adhering one surface of a plurality of semiconductor chips onto one surface of a substrate, forming a molding material surrounding the semiconductor chips on the substrate, forming a plurality of unit semiconductor packages by forming an adhesive layer on the other surface of the semiconductor chips and the molding material, and forming the multi-stack semiconductor package by directly stacking the plurality of unit semiconductor packages. The semiconductor chips may include a plurality of chip vias and the substrate may include a plurality of substrate vias electrically connected aligned to the chip vias.

The method may further comprise forming an uppermost semiconductor package including a protective layer thereon.

The substrate may be adhered onto the one surface of the semiconductor chips using an anisotropic conductive adhesive.

Forming the adhesive layer on the other surface of the semiconductor chips may include spraying an adhesive onto a support of a rigid material, and adhering the other surface of the semiconductor chips.

A temporary protective layer may be disposed on the rigid support and the adhesive may be sprayed onto the temporary protective layer.

The temporary protective layer may be removed before the substrate of the other unit semiconductor package is adhered.

The substrate may include via lands formed on one surface of the substrate and aligned with the substrate vias.

The substrate may include circuit lands formed on the other surface of the substrate and aligned with the substrate vias.

The substrate may include test lands formed on the other surface of the substrate and electrically connected to the circuit lands.

The method may further comprise forming a bottommost semiconductor package including conductive connectors on solder lands thereon.

### BRIEF DESCRIPTION OF THE DRAWINGS

Example embodiments are described in further detail below with reference to the accompanying drawings. It should be understood that various aspects of the drawings may have been exaggerated for clarity.

FIG. 1A is a cross-sectional view schematically illustrating a multi-stack semiconductor package according to example embodiments.

FIG. 1B is a cross-sectional view schematically illustrating a unit semiconductor package according to example embodiments.

FIG. 1C is an enlarged cross-sectional view schematically illustrating an adhesion portion of a substrate and a semiconductor chip of a unit semiconductor package according to example embodiments.

FIG. 1D is a cross-sectional view schematically illustrating a substrate of a unit semiconductor package disposed in a bottom portion of a multi-stack semiconductor package.

FIG. 2 is a diagram schematically illustrating top and bottom surfaces of a substrate of a unit semiconductor package according to example embodiments.

FIGS. 3A through 3C are cross-sectional views schematically illustrating a multi-stack semiconductor package according to example embodiments.

FIGS. 4A through 4C are cross-sectional views illustrating a multi-stack semiconductor package and a substrate used therein according to example embodiments.

FIGS. 5A through 5E are diagrams schematically illustrating a method of fabricating a multi-stack semiconductor package according to example embodiments.

FIGS. 6A through 6C are cross-sectional views schematically illustrating a method of fabricating a multi-stack semiconductor package according to example embodiments.

FIG. 7 is a diagram schematically illustrating a semiconductor module to which the multi-stack semiconductor package may be applied according to example embodiments.

FIG. 8 is a diagram schematically illustrating an electronic signal processing system having a semiconductor module including a multi-stack semiconductor package according to example embodiments.

### DETAILED DESCRIPTION

Example embodiments will now be described more fully with reference to the accompanying drawings in which example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the inventive concept is not limited to example embodiments described.

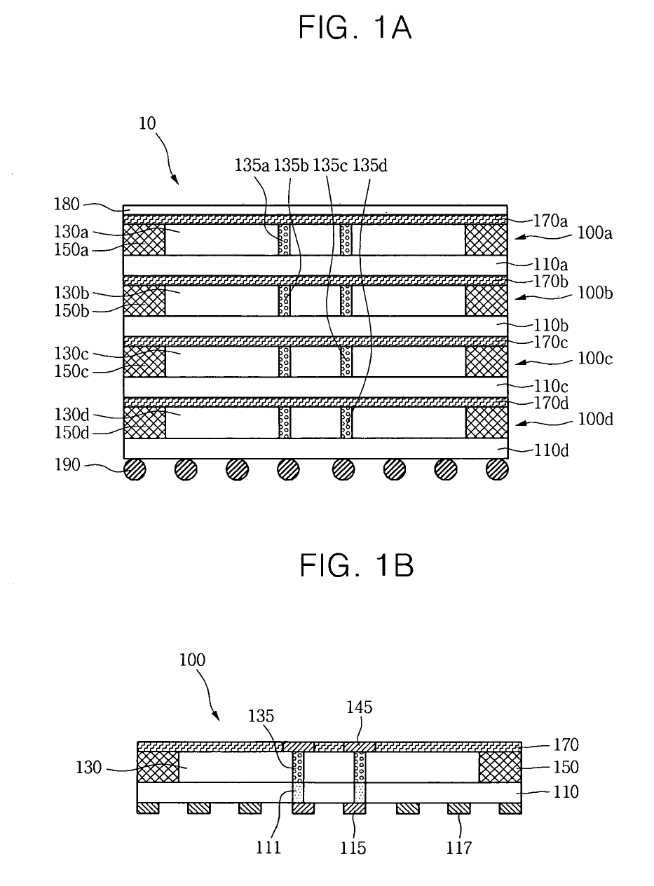

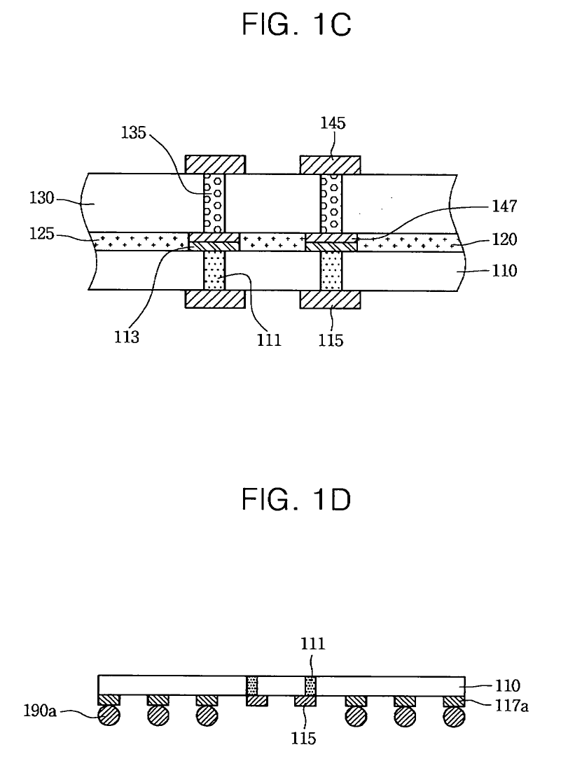

FIG. 1A is a cross-sectional view schematically illustrating a multi-stack semiconductor package 10 according to example embodiments, FIG. 1B is a cross-sectional view schematically illustrating a unit semiconductor package 100 according to example embodiments, FIG. 1C is an enlarged cross-sectional view schematically illustrating an adhesion portion of a unit substrate 110 and a unit semiconductor chip 130 of a unit semiconductor package 100 according to example embodiments, and FIG. 1D is a cross-sectional view schematically illustrating a unit substrate 110 of a unit semiconductor package 100 disposed in a bottommost portion of the multi-stack semiconductor package 10.

Referring to FIGS. 1A through 1D, a multi-stack semiconductor package 10 according to example embodiments may include a plurality of stacked semiconductor packages 100a-100d. Each of the semiconductor packages 100a-100d may include substrates 110a-110d, semiconductor chips 130a-130d having chip vias 135a-135d formed on the substrates 110a-110d, insulating molding materials 150a-150d filled around the semiconductor chips 130a-130d, adhesive layers 170a-170d formed on the semiconductor chips 130a-130d and the molding materials 150a-150d. FIG. 1B illustrates a unit semiconductor package 100 having a unit substrate 110, a unit semiconductor chip 130, a unit chip via 135, a unit insulating molding material 150, and a unit adhesive layer 170. The unit semiconductor package 100 may correspond to any one of the semiconductor packages 100a-100d having the substrates 110a-110d, the semiconductor chips 130a-130d, the chip vias 135a-135d, the insulating molding materials 150a-150d, and the adhesive layers 170a-170d. The multi-stack semiconductor package 10 may further include a protective layer 180 on the topmost semiconductor package 100a and/or conductive connectors 190 below the bottommost semiconductor package 100d.

In example embodiments, the four semiconductor packages 100a-100d may be stacked to form the multi-stack semiconductor package 10. However, example embodiments are not limited to a multi-stack semiconductor package having four semiconductor packages. For example, a multi-stack semiconductor package may have more or less than four stacked semiconductor packages. In example embodiments, at least two of the semiconductor packages 100a-100d may be stacked to form the multi-stack semiconductor package 10. Otherwise, a larger number of the semiconductor packages resembling any one of semiconductor packages 100a-100d may be stacked to form the multi-stack semiconductor package 10. In particular, the topmost semiconductor package 100a and the bottommost semiconductor package 100d may be configured to be different from the intermediate semiconductor packages 100b and/or 100c stacked therebetween.

Each of the semiconductor chips 130a-130d may include at least one of the conductive chip vias 135a-135d and may be electrically connected to at least one of the other semiconductor chips 130a-130d through the conductive chip vias 135a-135d. The chip vias 135a-135d may pass through at least one of the semiconductor chips 130a-130d and may be arranged in rows or columns across a center portion of each of the semiconductor chips 130a-130d. At least one of the chip vias 135a-135d may be arranged to overlap at positions where input/output pads of the semiconductor chips 130a-130d are formed. When the input/output pads are formed not in the center portion but in an outer portion, the chip vias 135a-135d may be formed in the outer portion of the semiconductor chips 130a-130d. The chip vias 135a-135d may be formed by a process of processing a wafer. For example, chip via holes vertically passing through the wafer may be formed and filled with a conductive material, e.g., a metal, thereby forming the chip vias 135a-135d. The chip vias 135a-135d may be formed of a conductive material, for example, copper or a copper alloy.

The unit substrate 110 (one of the substrates 110a-110d) may include unit substrate vias 111. The unit substrate vias 111 may pass through the unit substrate 110 and be formed to overlap the unit chip vias 135. The unit substrate vias 111 may be electrically connected to the unit chip vias 135. As illustrated in FIG. 1B, the unit substrate vias 111 may be formed in a pillar shape, but need not necessarily be formed in the pillar shape. The unit substrate vias 111 may be formed in various shapes. For example, the unit substrate 110 may be formed in multiple layers and electrical connections may be formed using a plurality of wirings formed in vertical and horizontal directions. The unit substrate vias 111 may be formed by a process of processing the unit substrate 110, regardless of processes of processing a wafer.

Unit via pads 147 and/or unit via lands 113 may be formed between the unit substrate vias 111 and the unit chip vias 135. The unit via pad 147 may be connected to an upper via pad 145 through the unit chip via 135. The unit via pads 147 and the unit via lands 113 may be formed of metal, and only one of the unit via pads 147 and the unit via lands 113 may be formed or both may be formed. The unit via pads 147 and/or the unit via lands 113 may be formed and used like bumps. To avoid complexity in the drawings, the unit via pads 147 and the unit via lands 113 are illustrated in only FIG. 1C.

The unit substrate vias 111 may be electrically connected to the unit chip vias 135 through direct contact or an anisotropic conductive adhesive (ACA). The ACA may be used in the form of a film or paste. Therefore, the unit via pads 147 may be electrically connected to the unit via lands 113 through direct contact or ACA.

For the unit substrate 110, a printed circuit board (PCB) may be used as a semiconductor module substrate, a main board or a system board. The unit via lands 113 may be electrically connected to the unit semiconductor chip 130 and may be formed on one surface of the unit substrate 110, for example, a top surface of the unit substrate 110. The unit semiconductor package 100 may include a plurality of first and second unit bonding lands 115 and 117. The first unit bonding lands 115 may be circuit lands 115 to transfer real signals to the unit semiconductor chip 130 and the second unit bonding lands 117 may be test lands 117 to transfer test signals and real signals to the circuit lands 115 and the unit semiconductor chip 130. The second unit bonding lands 117 of the bottommost semiconductor package may be electrically connected to and/or physically in contacted with external elements e.g. a semiconductor sockets, semiconductor modules, or main circuit boards to transfer test signals and real signals. The circuit lands 115 may be electrically connected to the unit via lands 113 through the unit substrate vias 111. The test lands 117 may be electrically connected to the circuit lands 115 through substrate wirings (not illustrated).

Solder lands 117a, as shown in FIG. 1D, may be provided on a bottom surface of the unit substrate 110 and solder balls 190a may be formed on the solder lands 117a. The unit substrate 110 may correspond to the bottommost substrate 110d of semiconductor package 100d of the multi-stack semiconductor package 10 illustrated in FIG. 1A. Accordingly, the bottommost semiconductor package 100d may include solder balls 190a on solder lands 117a that may be on a bottom surface of the semiconductor package 100d.

An adhesive 120 may be present between the unit substrate 110 and the unit semiconductor chip 130. This will be described in fabrication processes of the multi-stack semiconductor package 10 according to example embodiments.

The molding materials 150a-150d may include epoxy resin, an electric mold material (e.g., electric mold compound (EMC)). The molding materials 150a-150d may protect the semiconductor chips 130a-130d from external electrical and physical impacts and smoothly transfer heat generated from the semiconductor chips 130a-130d to outside of the multi-stack package.

The semiconductor packages 100a-100d may be stacked and adhered to one another by the adhesive layers 170a-170d. Specifically, the adhesive layers 170a-170d may adhere the substrates 110a-110d onto the semiconductor chips 130a-130d. The adhesive layers 170a-170d may include epoxy resin. In FIGS. 1A through 1D, the size of the adhesive layers 170a-170d may be exaggerated.

The protective layer 180 may be formed on the adhesive layer 170a of the topmost semiconductor package 100a. The protective layer 180 may be formed of a rigid material. For example, the protective layer 180 may be formed of glass, ceramic, or an insulating rigid flat board. The protective layer 180 may protect the multi-stack semiconductor package 10 from external physical impacts.

The connectors 190 may electrically connect the multi-stack semiconductor package 10 to a circuit board, for example, the solder balls may be formed on a surface of the bottommost unit semiconductor package 100d. Although the figures illustrate the connectors 190 as comprising solder balls, example embodiments are not limited thereto. For example, the connectors 190 may be comprised of hexahedral or mesa shaped connectors and pin shaped connectors.

Lands 117a on which the connectors 190a may be formed may be formed on the bottommost semiconductor package 100d. In example embodiments, because the solder balls 190a may be formed as the connectors, the lands 117a may be referred to as solder lands 117a. The solder lands 117a may have an arrangement that is the same as, or different from, the test lands 117 formed on the unit substrate 110 of the other unit semiconductor packages 100.

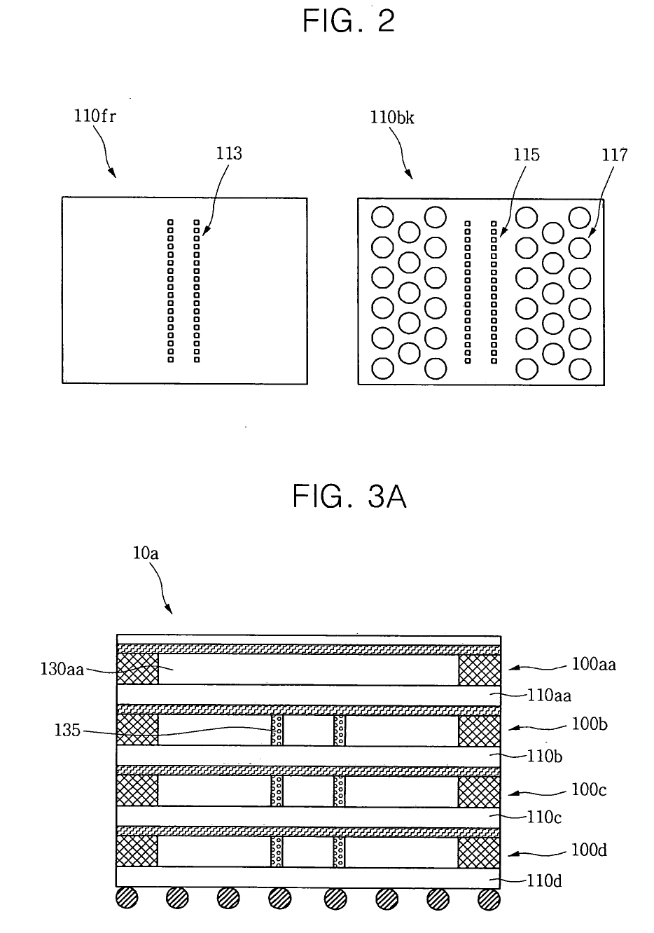

FIG. 2 is a diagram schematically illustrating different surfaces (for example, a front surface and a back surface) of the unit substrate 110 according to example embodiments. Referring to FIG. 2, the unit via lands 113 may be formed on one side 110fr of the unit substrate 110, and the circuit lands 115 and the test lands 117 may be formed on the another side 110bk. The circuit lands 115 may be electrically connected to the test lands 117 in one-to-one correspondence. An example in which the unit via lands 113 and the circuit lands 115 are arranged in two lines in a center portion of the unit substrate 110 is depicted, but example embodiments are not limited thereto. As described above, the unit via lands 113 may be electrically connected to the circuit lands 115 through unit substrate vias 111 and aligned with each other. The circuit lands 115 may be electrically connected to the test lands 117 in one-to-one correspondence. In the case of the bottommost substrate 110d, the solder lands 117a may be formed without the test lands 117. Also, on the bottommost substrate 110d, the circuit lands 115 may be electrically connected to the solder lands 117a in one-to-one correspondence. In FIG. 2, an example in which the test lands 117 are alternately arranged has been illustrated, but they may be arranged in a grid pattern. In FIG. 2, an example in which the unit via lands 113 and the circuit lands 115 are arranged in a rectangular shape has been illustrated, but example embodiments are not limited thereto.

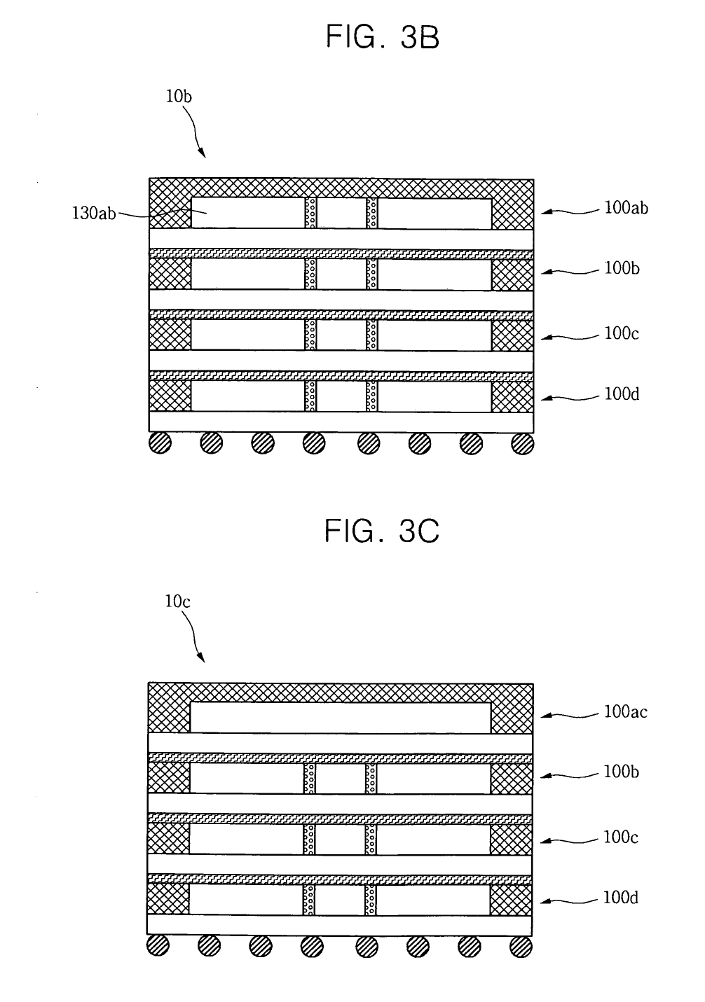

FIGS. 3A through 3C are cross-sectional views schematically illustrating a multi-stack semiconductor package 10a according to example embodiments. A multi-stack semiconductor package 10a according to example embodiments as illustrated in FIG. 3A may be different from the multi-stack semiconductor package 10 according to example embodiments illustrated in FIGS. 1A through 1D in that a topmost semiconductor package 100aa does not include chip vias 135. Because the topmost semiconductor package 100aa does not need to vertically transfer an electronic signal, the chip vias 135 need not be formed. In example embodiments, an active face of a semiconductor chip 130aa included in the topmost semiconductor package 100aa may be adhered in a substrate 110aa direction. Active faces of the other semiconductor chips in the semiconductor packages 100b-100d need not be in the substrates 110b-110d direction.

Referring to FIG. 3B, a multi-stack semiconductor package 10b according to example embodiments may not include any protective layers on a topmost semiconductor package 100ab. A molding material may be formed to cover a topmost semiconductor chip 130ab without forming any protective layers. When the protective layer is not formed, a top adhesive layer, similar to the adhesive layer 170a of FIG. 1A, may also not be formed.

Referring to FIG. 3C, a multi-stack semiconductor package 10c according to example embodiments may include neither chip vias nor a protective layer. The multi-stack semiconductor package 10c also may not include a top adhesive layer similar to the adhesive layer 170a illustrated in FIG. 1A.

Therefore, according to the FIGS. 3A through 3C, it may be sufficiently understood that the topmost semiconductor packages 100aa, 100ab, and 100ac of the multi-stack semiconductor packages 10a-10c may not necessarily need chip vias, adhesive layers, and/or protective layers.

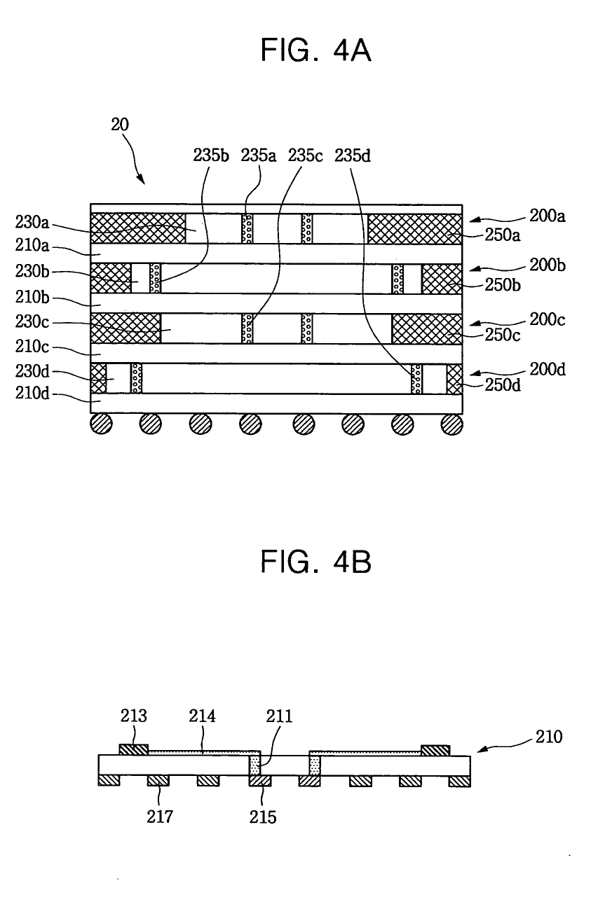

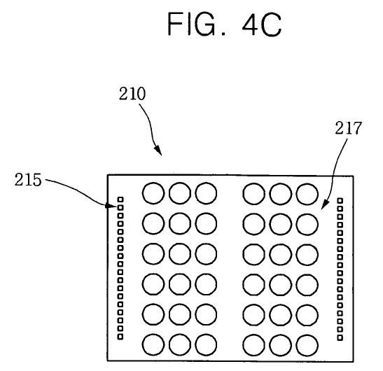

FIGS. 4A through 4C are cross-sectional views illustrating multi-stack semiconductor packages and substrates used therein according to example embodiments. Referring to FIG. 4A, a multi-stack semiconductor package 20 according to example embodiments may include a plurality of semiconductor packages 200a-200d. The semiconductor packages 200a-200d may include various substrates 210a-210d, various semiconductor chips 230a-230d on the various substrates 210a-210d, and various molding materials 250a-250d around the various semiconductor chips 230a-230d. In example embodiments, the semiconductor chips 230a-230d included in the semiconductor packages 200a-200d may have different specifications or standards, and the semiconductor chips 230a-230d may be integrated as one multi-stack semiconductor package 20.

The semiconductor packages 200a-200d applied in example embodiments may be stacked even when types and sizes of the semiconductor chips 230a-230d or positions of chip vias 235a-235b are different from each other. Specifically, each of the substrates 210a-210d may be separately fabricated on the basis of standards of each of the semiconductor chips 230a-230d. It should be understood that elements which are not illustrated in FIGS. 4A through 4C may all be applied as characteristic elements of example embodiments. These elements are not illustrated to avoid complexity in the drawings.

FIG. 4B illustrates a unit substrate 210 that may be used in the multi-stack semiconductor package 20 according to example embodiments. The unit substrate 210 may include via lands 213 and bonding lands 215 that are not overlapped or aligned with each other. The via lands 213 may be electrically connected to the bonding lands 215 through substrate wirings 214 and substrate vias 211. The substrate wirings 214 may be formed on any one surface of the unit substrate 210. However, because the unit substrate 210 may be formed in multiple layers, the substrate wirings 214 may be formed inside the unit substrate 210 or on interfaces between the multiple layers.

Referring to FIG. 4C, in the unit substrate 210 that may be used in the multi-stack semiconductor package 20 according to example embodiments, the bonding lands 215 may be arranged in an outer portion of the unit substrate 210 and test lands (indicated by reference numeral 217 or solder lands) may be arranged in a grid pattern. FIG. 4C is illustrated to compare the unit substrate 210 with the unit substrate 110. That is, the test lands (indicated by reference numeral 217 or the solder lands) may be arranged in a alternating zigzag pattern.

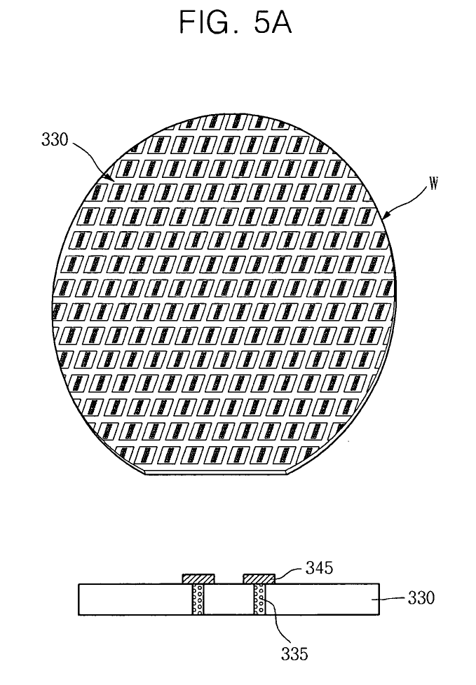

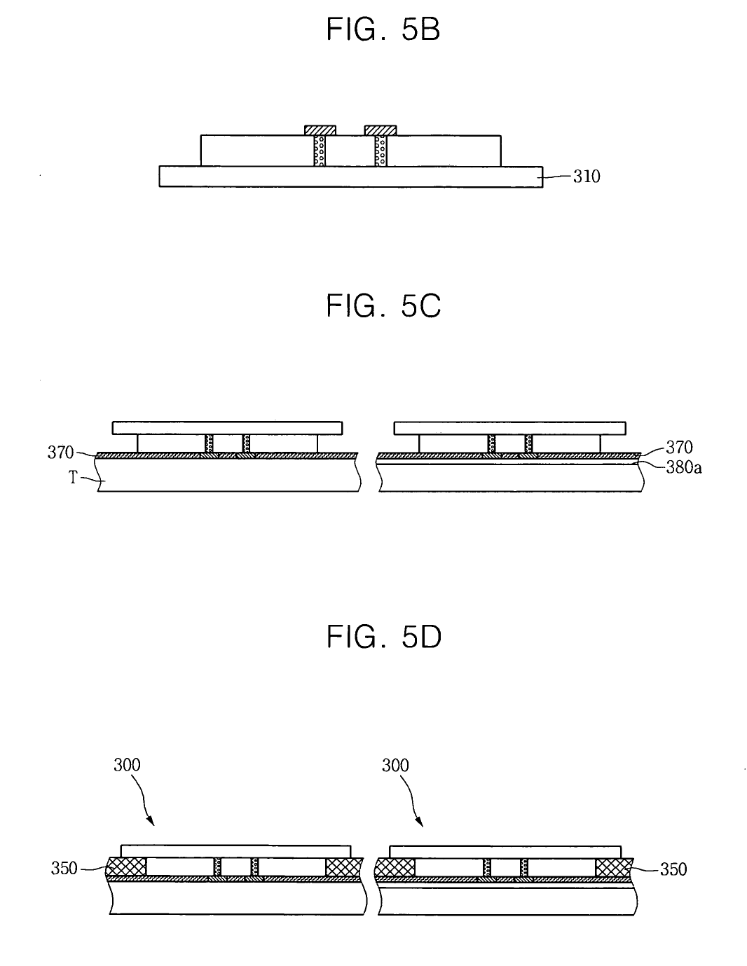

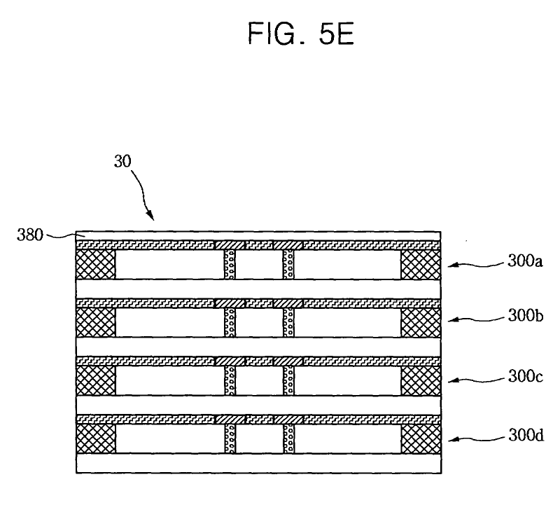

FIGS. 5A through 5E are diagrams schematically illustrating a method of fabricating a multi-stack semiconductor package according to example embodiments. Referring to FIG. 5A, chip vias 335 may be formed in semiconductor chips 330 in a wafer (W) state. Completion of the semiconductor chips 330 in the wafer (W) state may mean that a topmost metal interconnection layer is completed. A plurality of semiconductor chips 330 may be formed on the wafer W and a wafer level redistribution formed thereon may be included. In example embodiments, the chip vias 335 may be formed to vertically pass through the wafer W. In example embodiments, via pads 345 may be formed on the chip vias 335. The chip vias 335 may be formed after forming via holes passing through the wafer W using an etching method and filling the via holes using, for example, a plating method. A passivation layer (not illustrated) may be formed on an upper surface of the semiconductor chips 330. The passivation layer may be formed on the surface of the semiconductor chip 330 and may be configured to externally expose the surfaces of the chip vias 335 or via pads 345.

In the above-described processes, the wafer W may be thinned. In the wafer thinning process, the wafer W may be thinned by grinding a backside of the wafer using, for example, a grinder. As a wafer thinning method currently proposed, technology for plasma-etching the backside of the wafer W has been introduced. That is, various techniques for thinning the wafer W may be applied to example embodiments.

Referring to FIG. 5B, the semiconductor chips 330 in the wafer state may be separated into individual chips and adhered onto a substrate 310. The process of separating the semiconductor chips 330 of the wafer state is called a sawing process. In example embodiments, the semiconductor chips 330 may or may not be individually separated one by one. In other words, two or more semiconductor chips 330 may be separated as one device unit. In example embodiments, the semiconductor chips to be separated as one device unit may be fabricated to be electrically connected in a design or process. In example embodiments, an active face of the semiconductor chip 330 may be on a surface of the semiconductor chip 330 opposing the surface of the semiconductor chip 330 attached to the substrate 310. Alternatively, the active face of the semiconductor chip 330 may be simply adhered to be in a direction of the substrate 310 according to a design.

As described above, the substrate 310 may be a PCB for a package. A size of the substrate 310 does not depend on an area of the semiconductor chip 330. This process may be performed by pasting an adhesive on the substrate 310 using die attachment equipment, and heating and pressing each semiconductor chip 330 at a temperature of several tens or hundreds of degrees Celsius. The adhesive may include a film or paste of an epoxy resin.

In this process, chip vias 335 of the semiconductor chip 330 may be electrically connected to via lands on the substrate 310. The adhesive may or may not have conductivity. For example, the adhesive may be an ACA or a non-conductive adhesive (NCA).

Referring to FIG. 5C, an adhesive layer 370 may be formed on a surface of the semiconductor chips 330 that is different from a surface to which the substrate 310 is adhered. The left figure of FIG. 5C illustrates an example in which a protective layer 380 (see FIG. 5E) is not formed and the right figure illustrates an example in which a temporary protective layer 380a is formed. These processes may be performed on a supporting plate table T of a rigid material. For example, in a state in which the semiconductor chips 330 adhered onto the substrate 310 are reversed (turned upside down) on the rigid supporting plate table T, the adhesive layer 370 may be formed. In a unit semiconductor package 300a (see FIG. 5E) that may be disposed in a top portion of a multi-stack semiconductor package 30, the adhesive layer 370 and the protective layer 380 may be formed on a side the semiconductor package 300a opposing the side of the semiconductor package 300a to which a substrate, for example, the substrate 310, is attached. Specifically, a protective layer 380 may be disposed on the rigid supporting plate table T and an adhesive layer 370 may be formed on the protective layer 380 and the semiconductor chip 330 may be adhered onto the adhesive layer 370.

As described above, the protective layer 380 may be formed of a rigid material. For example, the protective layer 380 may be formed of glass, ceramic, or an insulating rigid and flat board. Rather than forming a protective layer 380 on the unit semiconductor package 300a disposed in the top portion of the multi-stack semiconductor package 30, a temporary protective layer 380a may be formed. That is, the temporary protective layer 380a may be formed in the process of forming the adhesive layer 370, but may be removed in another process. The temporary protective layer 380a does not need to be formed of the same material as the protective layer 380. In example embodiments, the temporary protective layer 380a capable of being formed relatively easily may be, for example, glass. In this process, the semiconductor chips 330 are connected to the substrates 310 in one-to-one correspondence, but one adhesive layer 370 may be formed on one surface of the semiconductor chips 330.

Referring to FIG. 5D, the semiconductor chips 330 may be molded. In a state in which the adhesive layer 370 is formed on the one surface of the semiconductor chips 330, a molding material 350 may be used to fill spaces between the substrate 310 and the adhesive layer 370 in a peripheral portion of the semiconductor chip 330. The surface of the molding material 350 may be formed not to be higher than that of the substrate 310. That is, the surface height of the molding material 350 may be formed to be equal to or lower than that of the substrate 310. In FIG. 5D, an example in which the surface of the molding material 350 is substantially the same as a lower surface of the substrate 310 in height has been illustrated to avoid complexity in the drawings. The molding material 350 may include epoxy resin and may be formed of an insulating material having viscosity. The molding material 350, for example, may be a thermosetting material.

The molded semiconductor chips 330 may be individually separated according to the size of each substrate 310. Each of the individually separated semiconductor chips 330 may be formed as the unit semiconductor package 300. Specifically, a plurality of semiconductor chips adhered onto one adhesive layer 370 or semiconductor chips 330 disposed on one temporary protective layer 380a may be separated into individual semiconductor packages 300 by a separating process, for example, a sawing process.

Referring to FIG. 5E, a plurality of semiconductor packages 300a-300d may be stacked in layers. In this process, the temporary protective layer 380a of the unit semiconductor packages 300b-300d disposed in middle and bottom portions may be removed. That is, the adhesive layer 370 may be exposed and adhered onto the substrate 310 of other unit semiconductor packages. The unit semiconductor package 300d disposed in the bottom portion may include the substrate 310 on which the solder lands (not shown) are formed, and the semiconductor package 300a disposed in the top portion may include the protective layer 380. When solder lands are formed to be compatible with test lands in the process of fabricating the substrate 310, the bottommost semiconductor package 300d may have compatibility with the unit semiconductor packages 300b and 300c disposed in the middle portion. Thereafter, the solder balls, for example, may be formed, thereby completing the multi-stack semiconductor package 10 as illustrated in FIG. 1A.

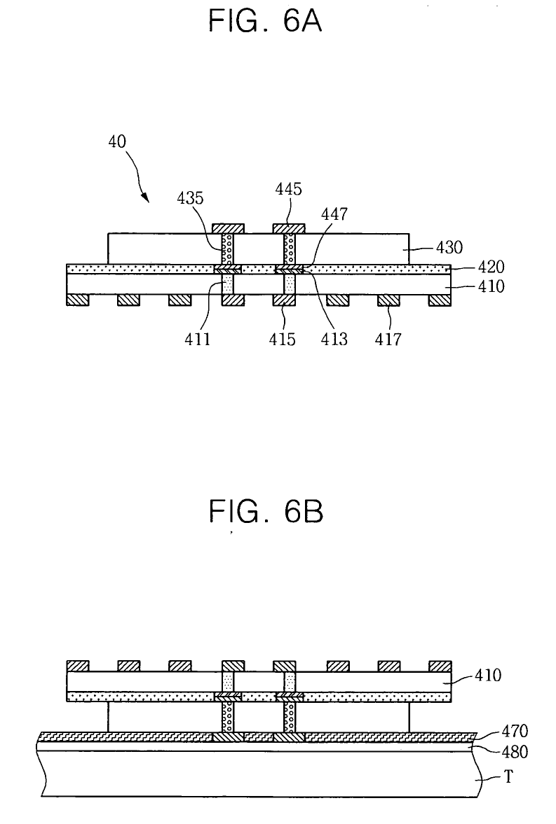

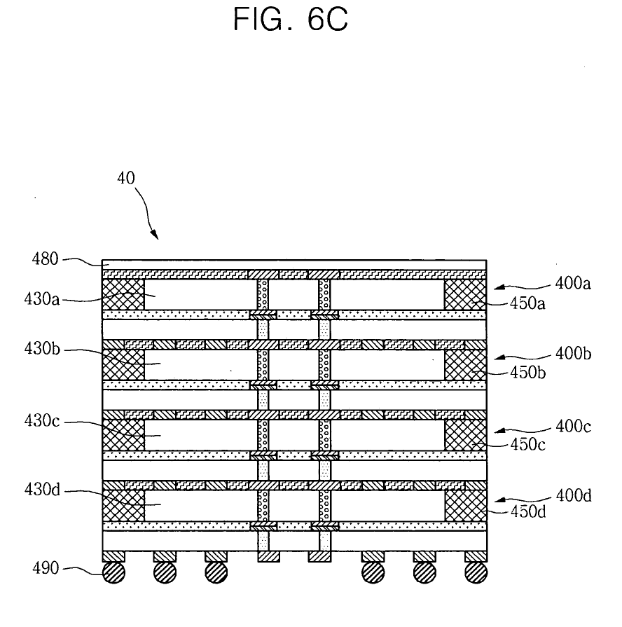

FIGS. 6A through 6C are cross-sectional views schematically illustrating a method of fabricating a multi-stack semiconductor package according to example embodiments. Referring to FIG. 6A, a semiconductor chip 430 in a wafer state that is individually separated is adhered onto a substrate 410. The semiconductor chip 430 may include chip vias 435 and upper via pads 445. The chip vias 435 may be electrically connected to via lands 413, in particular, through lower via pads 447. The substrate 410 may include substrate vias 411, the via lands 413, bonding lands 415, and solder lands 417. The semiconductor chip 430 may be adhered onto the substrate 410 using an adhesive 420.

Referring to FIG. 6B, an adhesive layer 470 and a protective layer 480 may be formed on a surface of the semiconductor chip 430 that is different from a surface of the semiconductor chip 430 adhered to the substrate 410. In a state in which the semiconductor chips 430 adhered to the substrate 410 are reversed (turned upside down), the adhesive layer 470 and the protective layer 480 may be adhered onto a supporting plate table T of a rigid material. In example embodiments, the protective layer 480 may be a layer that is only temporarily adhered.

Referring to FIG. 6C, the semiconductor chips 430a-430d may be molded with molding materials 450a-450d, separated into unit semiconductor packages 400a-400d, and stacked in multiple layers, thereby completing the method of fabricating the multi-stack semiconductor package 40 according to example embodiments. After the unit semiconductor packages 400a-400d are stacked, conductive connectors 490, for example, solder balls, may be formed on the bottommost semiconductor package 400d disposed in the bottom portion of the multi-stack semiconductor package 40. For reference, test lands of substrates are illustrated between a bottom surface of the semiconductor package 400d and the connectors 490.

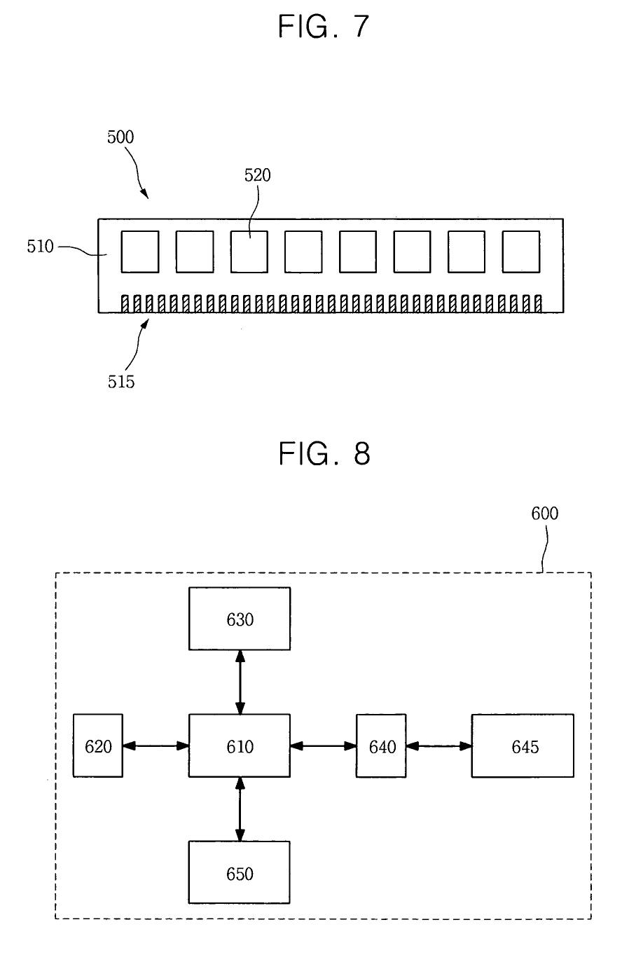

FIG. 7 is a diagram schematically illustrating a semiconductor module to which the multi-stack semiconductor package is applied according to example embodiments. Referring to FIG. 7, a semiconductor module 500 according to example embodiments may include a module substrate 510, one or more multi-stack semiconductor packages 520 formed on the module substrate 510, and contact terminals 515. The multi-stack semiconductor packages 520 may include multi-stack unit semiconductor packages. Each semiconductor package may include a substrate, a semiconductor chip formed on the substrate, an insulating molding material filled around the semiconductor chip, and an adhesive layer formed on the semiconductor chip and the molding material. The multi-stack semiconductor packages 520 may be sufficiently understood from the multi-stack semiconductor packages 10-40 illustrated and described with reference to FIGS. 1A through 6C.

The contact terminals 515 of the semiconductor module 500 are electrically connected to the multi-stack semiconductor packages 520, but connection wirings are omitted to avoid complexity in the drawings.

FIG. 8 is a diagram schematically illustrating an electronic signal processing system having a semiconductor module including a multi-stack semiconductor package according to example embodiments. In particular, an example in which a semiconductor module including a multi-stack semiconductor package is a memory module has been illustrated. Referring to FIG. 8, an electronic signal processing system 600 having the semiconductor module including the multi-stack semiconductor package may include a central processing unit (CPU) 610, a command unit 620, an output unit 630, a memory interface 640, a semiconductor module 645, and an external communicator 650. The electronic signal processing system 600 may be a well-known computer system.

The command unit 620 may be a unit for inputting a signal processing command to be output to the CPU 610, for example, a computer keyboard, a mouse, or a touch pad.

The output unit 630 may be a unit for externally displaying signal processing results, for example, a display, a monitor, or a printer.

The semiconductor module 645 may be a unit for exchanging data with the CPU 610 and temporarily or semi-permanently storing the data.

The memory interface 640 may be a memory controller, which may be disposed between the CPU 610 and the semiconductor module 645. The memory interface 640 may output data from the CPU 610 to the semiconductor module 645 or from the semiconductor module 645 to the CPU 610.

The communicator 650 may be a unit for transmitting or receiving an electronic signal. Specifically, the CPU 610 may transmit signal processing results to another electronic signal processing system or CPU, or receive a signal to be processed by the CPU 610 or an electronic signal to be referred to for signal processing.

In a multi-stack semiconductor package according to example embodiments, each unit semiconductor package may be tested and have a relatively fast and relatively inexpensive fabrication process, thereby improving productivity and performance. Therefore, a semiconductor module and an electronic signal processing system having the same according to example embodiments may have relatively high productivity and relatively excellent performance.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A multi-stack semiconductor package comprising:
stacked semiconductor packages including a topmost semiconductor package and a bottommost semiconductor package, each of the semiconductor packages including
a substrate including
at least one via land on a first surface of the substrate,
at least one circuit land on a second surface of the substrate and electrically connected to the at least one via land, and
at least one test land on the second surface of the substrate and electrically connected to the at least one circuit land,
a semiconductor chip on the substrate, the semiconductor chip including
at least one conductive chip via passing through the semiconductor chip, and
at least one lower via pad on a first surface of the semiconductor chip, the at least one lower via pad being electrically connected to the at least one conductive chip via and the at least one via land,
a molding material around the semiconductor chip on the substrate, and
an adhesive layer on the semiconductor chip and the molding material,
wherein the substrate of an upper semiconductor package stacked in an upper portion of the multi-stack semiconductor package is adhered to the adhesive layer of a lower semiconductor package stacked in a lower portion of the multi-stack semiconductor package.

2. The multi-stack semiconductor package according to claim 1, wherein at least one of the substrates includes at least one substrate via passing through the substrate electrically connecting the at least one via land to the at least one circuit land.

3. The multi-stack semiconductor package according to claim 2, wherein at least one of the substrates includes substrate wirings on a surface of the substrate electrically connected to the at least one substrate via.

4. The multi-stack semiconductor package according to claim 2, wherein at least one of the substrates is multi-layered.

5. The multi-stack semiconductor package according to claim 1, further comprising:
a protective layer on the topmost semiconductor package.

6. The multi-stack semiconductor package according to claim 1, wherein the at least one lower via pad is aligned with the at least one via land.

7. The multi-stack semiconductor package according to claim 1, wherein the semiconductor chip is adhered to the substrate by an adhesive, and the at least one lower via pad is electrically connected to the at least one via land using an anisotropic conductive adhesive.

8. The multi-stack semiconductor package according to claim 1, wherein the substrate of the bottommost semiconductor package includes at least one substrate via passing through the substrate of the bottommost semiconductor package, the at least one substrate via of the bottommost semiconductor package electrically connecting the at least one via land of the bottommost semiconductor package to the at least one circuit land of the bottommost semiconductor package.

9. The multi-stack semiconductor package according to claim 8, wherein the substrate of the bottommost semiconductor package further includes at least one solder land electrically connected to the at least one circuit land of the bottommost semiconductor package.

10. The multi-stack semiconductor package according to claim 9, further comprising:
at least one conductive connecters on the at least one solder land of the bottommost semiconductor package.

11. The multi-stack semiconductor package according to claim 1, wherein the at least one conductive chip via is in a center area of the semiconductor chip.

12. The multi-stack semiconductor package according to claim 1, wherein the at least one conductive chip via and the at least one lower via pad are aligned.

13. The multi-stack semiconductor package according to claim 1, wherein the semiconductor chip further includes at least one upper via pad on a second surface of the semiconductor chip electrically connected to the at least one chip via.

14. The multi-stack semiconductor package according to claim 13, wherein the at least one upper via pad and the at least one conductive chip via are aligned with each other.

15. The multi-stack semiconductor package according to claim 13, wherein the at least one lower via pad of the upper semiconductor package and the at least one upper via pad of the lower semiconductor package are electrically connected to each other.

16. The multi-stack semiconductor package according to claim 1, wherein the at least one circuit land is arranged in center area of the substrate and the at least one test land is in outer area of the substrate.

17. The multi-stack semiconductor package according to claim 1, wherein the stacked semiconductor packages includes at least one intermediate semiconductor package between the topmost semiconductor package and the bottommost semiconductor package.

18. A multi-stack semiconductor package comprising:
stacked semiconductor packages including a topmost semiconductor package, an intermediate semiconductor package, and a bottommost semiconductor package, each of the topmost semiconductor package and the intermediate semiconductor package including:
a substrate including,
at least one via land on a first surface of the substrate;
at least one circuit land on a second surface of the substrate and electrically connected to the at least one via land, the at least one circuit land being arranged in center area of the substrate;
at least one substrate via passing through the substrate electrically connecting the at least one via land to the at least one circuit land; and
at least one test land on the second surface of the substrate and electrically connected to the at least one circuit land, the at least one test land being arranged in an outer area of the substrate;
a semiconductor chip on the substrate, the semiconductor chip including,
at least one conductive chip via passing through the semiconductor chip, the at least one conductive chip via being arranged in a center area of the semiconductor chip;
at least one lower via pad on a first surface of the semiconductor chip, the at least one lower via pad being electrically connected to the at least one conductive chip via and the at least one via land; and
at least one upper via pad on a second surface of the semiconductor chip, the at least one upper via pad being electrically connected to the at least one conductive chip via and the at least one lower via pad,
wherein at least one upper via pad, the at least one conductive chip via, the at least one lower via pad, the at least one via land, at least one substrate via, and the at least one circuit land are aligned with one another,
wherein the substrate of the bottommost semiconductor package includes,
at least one substrate via passing through the substrate of the bottommost semiconductor package;
at least one solder land electrically connected to the at least one circuit land of the bottommost semiconductor package, at least one conductive connecter on the at least one solder land of the bottommost semiconductor package; and
the at least one substrate via of the bottommost semiconductor package electrically connecting the at least one via land of the bottommost semiconductor package to the at least one circuit land of the bottommost semiconductor package,
a molding material around the semiconductor chip on the substrate;
an adhesive layer on the semiconductor chip and the molding material; and
a protective layer on the topmost semiconductor package,
wherein the substrate of an upper semiconductor package stacked in an upper portion of the multi-stack semiconductor package is adhered to the adhesive layer of a lower semiconductor package stacked in a lower portion of the multi-stack semiconductor package.

19. A semiconductor module comprising:
a module substrate;
at least one multi-stack semiconductor package according to claim 1 on the module substrate; and
at least one contact terminal on the module substrate, wherein the at least one test land of the substrate of the bottommost semiconductor package and the at least one contact terminal are electrically connected to each other.

20. An electronic signal processing system comprising:
a central processing unit configured to process an electronic signal;
a command unit configured to output a signal processing command to the central processing unit;
an output unit configured to externally display the signal processed by the central processing unit;
a semiconductor module configured to exchange electronic data with the central processing unit and store the data;
a memory interface between the central processing unit and the semiconductor module; and
a communicator configured to receive a signal to be processed by the central processing unit from a second central processing unit and transmit a signal processed by the central processing unit to another central processing unit,
wherein the semiconductor module includes at least one multi-stack semiconductor package according to claim 1.
